(19) United States
(12) Patent Application Publication
(10) Pub. No.: US 2023/0032146 A1
(43) Pub. Date: Feb. 2, 2023

(54) SIMULTANEOUS IN PROCESS METROLOGY FOR CLUSTER TOOL ARCHITECTURE

(71) Applicant: Applied Materials, Inc., Santa Clara, CA (US)

(72) Inventors: Kirankumar Neelasandra SAVANDAIAH, Bangalore (IN); Srinivasa Rao YEDLA, Bangalore (IN); Lakshmikanth Krishnamurthy SHIRAHATTI, Bangalore (IN); Thomas BREZOCZKY, Los Gatos, CA (US)

(21) Appl. No.: 17/386,489

(22) Filed: Jul. 27, 2021

(51) Int. Cl. G01N 21/95; G03F 7/20; G06T 7/00; H01L 21/66

(52) U.S. Cl. CPC G01N 21/9501; G03F 7/7065; G03F 7/70625; G03F 7/70675; G06T 7/0006; H01L 22/12; H01L 22/30; G06T 2207/10048; G06T 2207/30148

(57) ABSTRACT

The present disclosure generally provides for a system and method for measuring one or more characteristics of one or more substrates in a multi-station processing system using one or more metrology modules at a plurality of metrology stations. In one embodiment, a system controller is configured to cause the multi-station processing system to perform a method that includes processing a plurality of substrates at a plurality of processing stations, advancing one or more of the plurality of substrates to a respective metrology station, measuring one or more characteristics of the plurality of substrates at the respective metrology station, determining a processing performance metric based on the one or more characteristics, comparing the processing performance metric to a tolerance limit to determine if an out of tolerance condition has occurred, and adjusting one or more processing parameters when it is determined that an out of tolerance condition has occurred.

### BACKGROUND

### Field

The present disclosure is generally directed to apparatus and methods used in electronic device manufacturing, and more particularly, to systems for forming multi-layer thin film stacks in a semiconductor device manufacturing process and in-line metrology systems used therewith.

### Description of the Related Art

Conventional methods of thin film deposition include physical vapor deposition (PVD), atomic layer deposition (ALD) and chemical vapor deposition (CVD). Often times, the conventional methods of thin film deposition result in a variety of inconsistencies. Thus, to monitor and modify growth parameters, metrology is used before, after, or during substrate processing to measure various film layer properties and determine film layer and substrate characteristics therefrom, such as film layer thickness and warping of the substrate.

Typical metrology methods often use standalone metrology systems that are separate from the substrate processing systems, or metrology systems that are coupled to the substrate processing system, to perform post-process measurements used for statistical process control (SPC). However, using post-process metrology systems to perform process control measurements creates a manufacturing control point too far downstream to avoid significant process drift, and in some cases device yield loss. For example, in the event a process deviates from statistical process control limits (i.e., an out-of-control event) the increased response time associated with using post-process metrology means that substrates subsequently processed in the system are also likely to exhibit properties or characteristics outside of the process control limits.

Accordingly, what is needed in the art are process control schemes and related systems that address the problems described above.

### SUMMARY

The present disclosure generally provides for an apparatus and methods for measuring one or more characteristics of one or more substrates in a multi-station processing system using in-line metrology systems disposed in a substrate transfer path between adjacent processing stations.

The present disclosure generally relates to a system for processing a plurality of substrates comprising a multi-station processing system that includes a processing chamber, a plurality of processing stations disposed in the transfer volume, a substrate handling system, a plurality of metrology stations each respectively disposed between adjacent processing stations of the plurality of processing stations, and a system controller. The system controller includes a non-transitory computer readable medium configured to cause the multi-station processing system to perform a method, comprising processing a plurality of substrates at the plurality of processing stations, advancing the plurality of substrates so that one or more of the plurality of substrate are positioned at a respective metrology station of the plurality of metrology stations, measuring one or more characteristics of the one or more of the plurality of substrates in the multi-station processing system using a metrology system at the respective metrology station, determining a processing performance metric, based on the one or more characteristics, and comparing the processing performance metric to a tolerance limit to determine if an out of tolerance condition has occurred, and adjusting one or more processing parameters when it is determined that an out of tolerance condition has occurred.

Embodiments of the present disclosure further include a system for processing a plurality of substrates comprising a multi-station processing system comprising a processing chamber, a plurality of processing stations disposed in the transfer volume, a substrate handling system, a plurality of metrology stations, each respectively disposed between adjacent processing stations of the plurality of processing stations, and a system controller. The system controller includes a non-transitory computer readable medium configured to cause the multi-station processing system to perform a method comprising processing the plurality of substrates at the plurality of processing stations, advancing the plurality of substrates so that one or more of the plurality of substrates are positioned at a respective metrology station of the plurality of metrology stations, measuring one or more characteristics of the plurality of substrates in the multi-station processing system using a metrology system at the respective metrology station, determining a first processing performance metric based on the one or more characteristics, and comparing the first processing performance metric to a first tolerance limit to determine if an out of tolerance condition has occurred, determining a second processing performance metric based on the one or more characteristics, and comparing the second processing performance metric to a second tolerance limit to determine if an out of tolerance condition has occurred, adjusting one or more processing parameters when the first processing performance metric is outside of the first tolerance limit, and adjusting one or more processing parameters when the second processing performance metric is outside of the second tolerance limit.

Embodiments of the present disclosure further includes a system for processing a substrate comprising a chamber, and a plurality of process stations disposed in the transfer volume, each fluidly isolated from the transfer volume, and each having a corresponding substrate processing position, wherein each substrate processing position collectively defines a circular transfer path a substrate handling system configured to move a plurality of substrates along the circular transfer path. The system for processing a substrate further includes one or more metrology stations respectively disposed between adjacent processing stations of the plurality of processing stations, and a system controller electronically coupled to the plurality of processing stations and the substrate handling system.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic plan view of a processing system that includes a multi-station processing chamber with intermittent metrology stations, according to one or more embodiments.

FIG. 2A is a schematic isometric view of the multi-station processing chamber of FIG. 1, according to one or more embodiments.

FIG. 2B is a schematic plan view of the multi-station processing chamber of FIG. 1, according to one or more embodiments.

FIG. 3A is a schematic isometric view of a substrate handling system that may be used with the multi-station processing chamber of FIG. 1, according to one embodiment.

FIG. 3B is a schematic top-down view of a substrate handling system that may be used in the multi-station processing chamber of FIG. 1, according to another embodiment.

FIG. 4 is a schematic top-down view illustrating a portion of a substrate transfer path in the multi-station processing chamber of FIG. 1 according to one embodiment of the processing chamber.

FIG. 5A is a schematic cross-sectional view of the multi-station processing chamber formed along the sectioning line 5A-5A illustrated in FIG. 2B, according to one or more embodiments.

FIG. 5B is a schematic cross-sectional view of the multi-station processing chamber formed along the sectioning line 5B-5B illustrated in FIG. 2B, according to another embodiment.

FIGS. 6A-6C schematically illustrate different metrology systems that may be used with the multi-station processing chamber of FIG. 1, according to one embodiment.

FIG. 7 is a diagram of a substrate processing method which may be performed using the multi-station processing chamber of FIG. 1, according to at least one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Aspects of the disclosure provided herein generally provide for a substrate processing system that includes a plurality of metrology stations respectively disposed between adjacent processing stations of the plurality of processing stations disposed in a transfer chamber that includes a substrate transferring device for transferring a plurality of substrates to two or more of the plurality of processing stations.

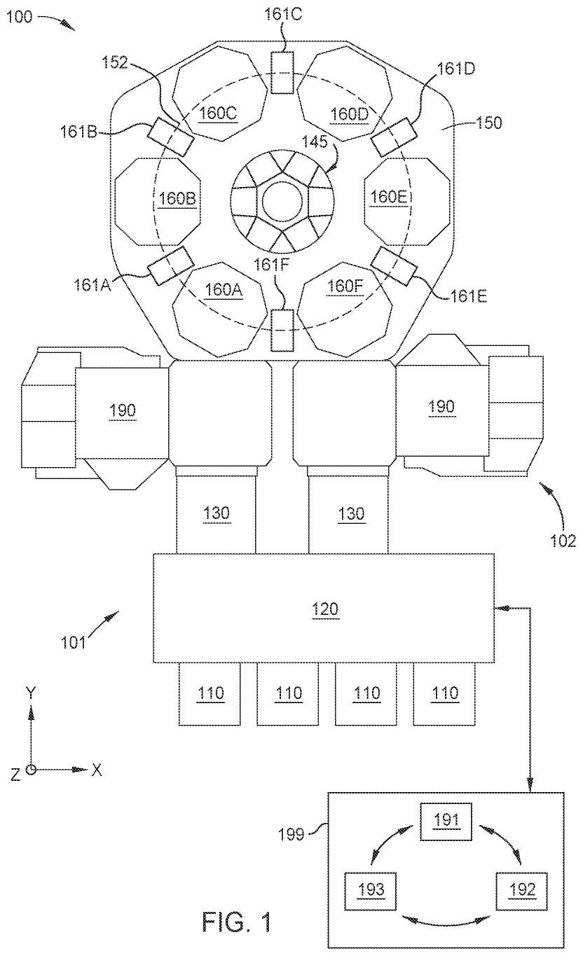

FIG. 1 is a substrate processing system 100 according to one embodiment. The substrate processing system 100 includes a factory interfacing portion 101, a pre-processing portion 102, and a multi-station processing chamber 150. The factory interfacing portion 101 is connected to the multi-station processing chamber 150 via the pre-processing portion 102. A system controller 199 is coupled to the substrate processing system 100 for controlling various functions and processes described herein. Typically a substrate is transferred from the factory interfacing portion 101 to the pre-processing chambers 190, to the multi-station processing chamber 150. The multi-station processing chamber 150 includes a plurality of process stations 160A-160F, and a plurality of metrology stations 161A-161F respectively disposed between adjacent process stations 160A-160F. The factory interfacing portion 101 includes a substrate handling area 120 having a substrate handler (not shown) disposed therein (e.g., a robot disposed therein), a plurality of cassettes 110 (four shown) or FOUPs attached thereto, and one or more load lock chambers 130 connected to the substrate handling area 120. The substrate handler (not shown) is used to receive and transfer substrates from the cassettes 110 or FOUPs to the load lock chambers 130 before the substrates are received into the pre-processing portion 102. Generally, the substrate handling area 120 is at atmospheric pressure and the pre-processing portion 102 and multi-station processing chamber 150 are maintained at sub-atmospheric pressure, such as under vacuum. The load lock chambers 130 are typically configured with pumps, valves, and doors that facilitate transferring substrates between atmospheric and sub-atmospheric conditions, and vice versa. The pre-processing portion 102 includes one or more pre-processing chambers 190, such as pre-clean and/or degas chambers (not shown), used to remove undesired contaminates from the substrate surface prior to processing, and one or more robots, disposed therein that may be used to transfer substrates between the load lock chambers 130, the pre-processing chambers 190, and the multi-station processing chamber 150.

While FIG. 1 illustrates the multi-station processing chamber 150 including six process stations 160A-160F, and six metrology stations 161A-161F, this configuration is not intended to be limiting, since the multi-station processing chamber 150 might alternatively include: two or more process stations 160; four or more process stations 160; eight or more process stations 160; ten or more process stations 160; or twelve or more process stations 160, and two or more metrology stations 161; four or more metrology stations 161; eight or more metrology stations 161; ten or more metrology stations 161; or twelve or more metrology stations 161. In addition, the multi-station processing chamber 150 can include any non-even, non-correlating, number of process stations 160 and metrology stations 161. For example, a transfer chamber may have 5 process stations 160 and 3 metrology stations 161.

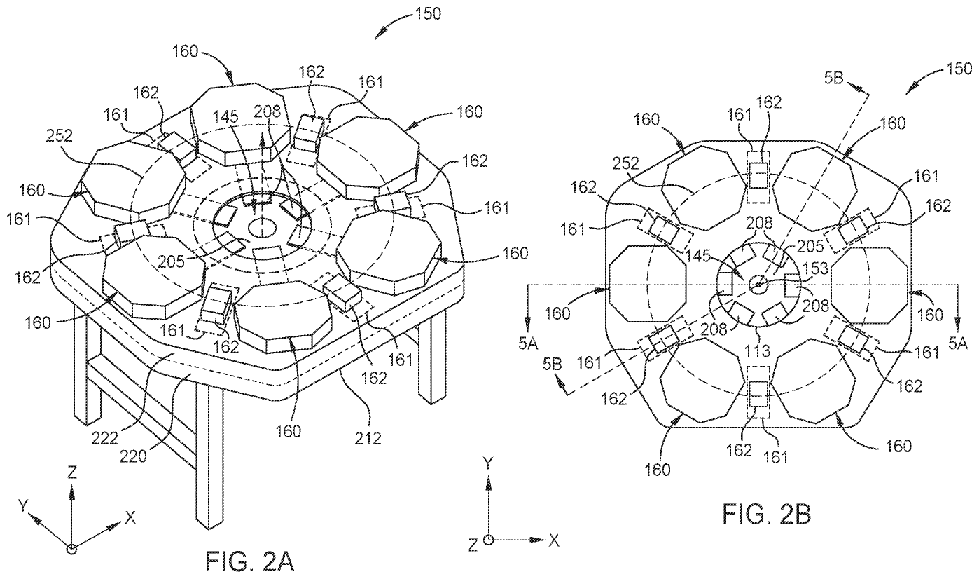

FIG. 1 further includes a substrate handling system 145 for moving substrates to and from the individual process stations 160A-160F and metrology stations 161A-F, along an imaginary circle of a circular substrate transfer path 152. The circular substrate transfer path 152 passes through the center of each of the plurality of process stations 160A-160F, and through the center of each of the plurality of metrology stations 161A-F. The process stations 160A-160F, the metrology stations 161A-161F, and the substrate handling system 145 are further described with reference to FIGS. 2A-6C below.

A substrate loaded into the multi-station processing chamber 150 need not be processed at each process station 160A-160F sequentially. For example, each process station 160A-160F can employ the same sputter target material so that multiple substrates can be processed concurrently in each process station 160A-160F for deposition of a same material layer. Alternatively, different processes are performed in each adjacent process station arrayed along a circle defined by a substrate transfer path. For example, a first deposition process to deposit a first type of film layer is performed in process stations 160A, 160C and 160E, and a second deposition process to deposit a second type of film layer is performed in process stations 160A, 160C, and 160E. In yet another alternative, the substrate is exposed to only two process stations. For example, a first substrate is exposed to only process stations 260A and 260B, a second substrate is exposed to only process stations 260C and 260D, and a third substrate is exposed to only process stations 260E and 260F. Thus, each substrate can be processed in any number of the process stations 160A-160F, and the processes performed at each process station 160A-160F can be the same or different from one or all of the remaining process stations 160A-160F.

The substrate processing system 100 further includes the system controller 199. The system controller 199 controls activities and operating parameters of the automated components found in the substrate processing system 100. In general, the bulk of the movement of a substrate through the processing system is performed using the various automated devices disclosed herein by use of commands sent by the system controller 199. The system controller 199 is a general use computer that is used to control one or more components found in the substrate processing system 100. The system controller 199 is generally designed to facilitate the control and automation of one or more of the processing sequences disclosed herein and typically includes a central processing unit (CPU) 191 which is operable with memory 192 (e.g., non-volatile memory), and support circuits 193. The support circuits 193 are conventionally coupled to the CPU 191 and comprise cache, clock circuits, input/output subsystems, power supplies and the like coupled to various components of the substrate processing system 100. The CPU 191 is one of any form of general purpose computer processors used in an industry setting, such as programmable logic controller (PLC), for controlling various components and sub-processors of the substrate processing system 100. Software instructions and data can be coded and stored within the memory (e.g., non-transitory computer readable medium) for instructing the CPU. A program (or computer instructions) readable by the processing unit within the system controller determines which tasks are performable in the processing system. For example, the non-transitory computer readable medium includes a program which when executed by the processing unit are configured to perform one or more of the methods described herein. Preferably, the program includes code to perform tasks relating to monitoring, execution and control of the movement, support, and/or positioning of a substrate along with the various process recipe tasks and various processing module process recipe steps being performed.

In FIGS. 2A-2B, the substrate handling system 145 includes a support shaft 205 and a plurality of support arms 208 coupled thereto. The support shaft 205 sealingly extends through a chamber base 212 and is rotated about a central axis 153 by an actuator (not shown), e.g., a carousel motor, positioned below the chamber base 212. The uppermost surface of a revolved volume through which the support arms 208 and a supporting portion 360 coupled thereto pass as they are rotated by the carousel motor is generally referred to herein as the transfer plane, which is parallel to the X-Y plane. The support shaft 205 and each of the support arms 208 are positioned within a transfer region of the multi-station processing chamber 150 that is separately evacuated by a vacuum pump which can be a turbopump, cryopump, roughing pump or other useful device that is able to maintain a desired pressure within the transfer region of the multi-station processing chamber 150. The support shaft 205 is generally positioned over a central opening formed in the lower wall of a lower monolith. As will be discussed further below, the transfer region and a processing region of a process station 160A-106F are separately isolatable so that processes being performed in a process station 160A-160F can be controlled and performed at a different vacuum pressure than the transfer region and use various different processing gases without the concern of contaminating the transfer region or other adjacently positioned process stations 160.

In some embodiments, support arms 208 are configured to support a substrate support that is configured to support a substrate that is to be processed in a processing region of a process station 160A-160F. Substrates that are positioned on the substrate supports, which are positioned on the support arms 208, are positioned so that the center of the substrate is positioned over a portion of the imaginary circle of the circular substrate transfer path 152, within tolerance limits of the placement of the substrate thereon. Likewise, the region of each of the support arms 208 on which a substrate support is placed, or supporting portion, is also aligned with the imaginary circle of the circular substrate transfer path 152 to allow the center of the supporting portion to traverse the imaginary circle of the circular substrate transfer path 152 as the supporting portion orbits around the central axis 153 when the support shaft 205 is rotated about the central axis 153.

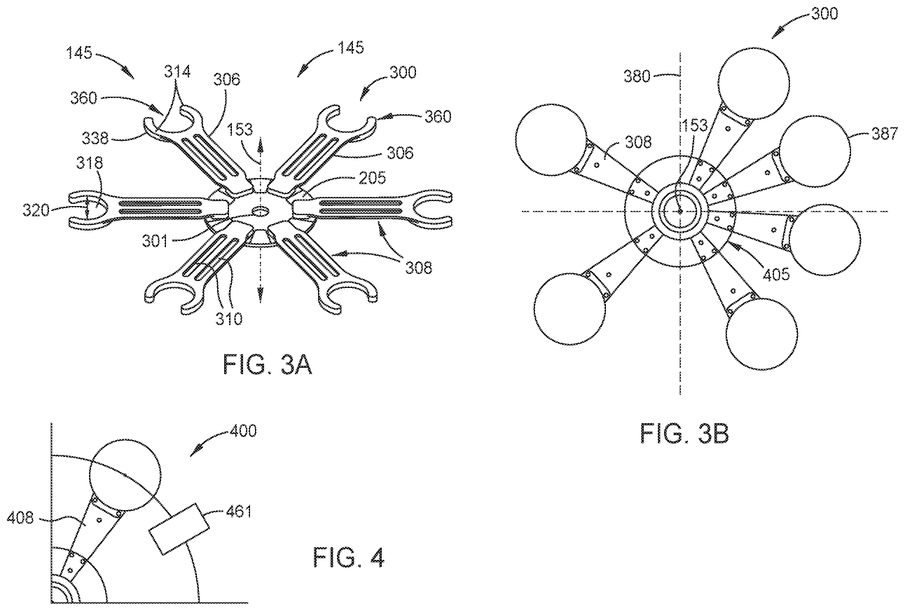

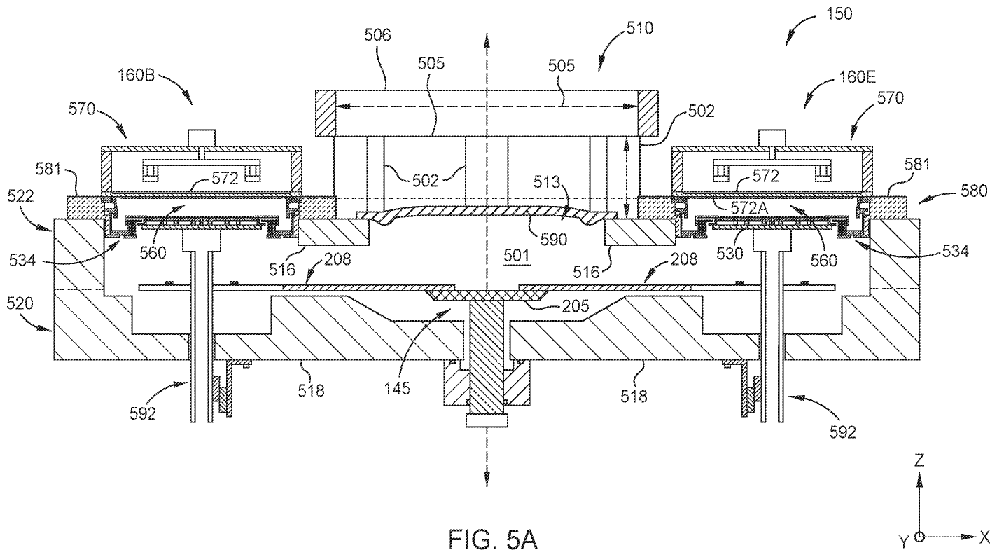

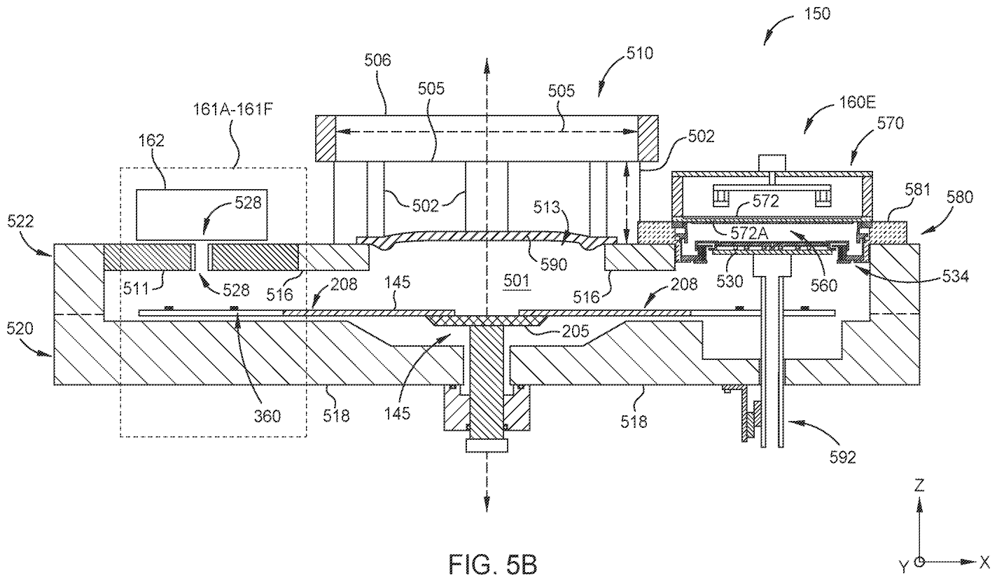

As seen in FIGS. 2A-2B each metrology station 161A-161F can include an upper metrology module 162 disposed on the upper monolith 222, above the chamber lid 511 (FIG. 5B) of the multi-station processing chamber 150, and a lower metrology module (not shown) disposed on the lower monolith 220, below the chamber base 212 of the multi-station processing chamber 150. The upper metrology module 162 is typically disposed above a window 528 (FIG. 5B). The window 528 may be fabricated from quartz, sapphire, or other material that is transparent. As seen in FIG. 2B, each metrology station 161A-161F is positioned above an imaginary circle of the circular transfer path 252 of the substrate, such that the substrate may be disposed beneath the upper metrology module 162 in the transfer region (not shown) of the multi-station processing chamber. FIG. 3A is one configuration of a carousel 300 of a substrate handling system 145 useful for transferring substrate supports between the process stations 160A-160F of FIGS. 2A and 2B. Here, the support shaft 205 includes a centrally located through opening 301, centered around the central axis 153 and into which the drive shaft of the carousel motor positioned below the multi-station processing chamber 150, is connected to cause rotation of the support shaft 205 about the central axis 153. Each transfer arm 308 includes an extension arm portion 306. The extension arm portion 306 has at least one, and here two, weight reduction and thermal heat conduction reducing cutout regions 310 that extend generally parallel to either side of a radius extending from the central axis 153. In some configurations, the extension arm portion 306 terminates at a c-shaped end region 338, as seen in plan view, and forms part of a supporting portion 360. In some configurations, the c-shaped end region 338 includes opposing ends 314 that are spaced apart a distance that is smaller than a diameter 320 of a through opening 318 that the c-shaped end region 338 partially surrounds.

Additionally, in one embodiment, a central transfer robot useful for transferring substrate supports between the process stations 160A-F of FIGS. 2A and 2B is a dual arm robot (not shown) that includes two end effectors. A central transfer robot that includes a dual arm robot can be useful in cases where a substrate processing sequence performed in a multi-station processing chamber 150 does not include or require the substrate to be sequentially transferred along a path that extends along the imaginary circle in either direction. In this multi-station processing chamber 150 configuration, the substrate supports need not be moveable in a lateral plane such that each substrate support maintained in one position in the X-Y plane beneath a process station 160A-160F, and during processing the substrates are transferred between the laterally fixed substrate supports by the dual arm robot.

FIG. 3B illustrates an example of a different transfer arm 308 configuration that can be used in a carousel 300, and is different from the transfer arm configuration of FIG. 3A. Here, the transfer arms 308 include chuck assemblies 387, which are not shown in FIG. 3A, and are configured to support a substrate on a substrate receiving surface formed thereon (i.e., top surface of the chuck assemblies 387). In some embodiments, one or more of the transfer arms 308 may be configured to transport a shutter disk (not shown) instead of a chuck assembly 387. In some embodiments, there may be more transfer arms 308 in one section 380 of the carousel 300 than another section such that the carousel 300 is differently loaded (such as 2 transfer arms 308 in one sector that span about half the circumference about the central axis 153 and 4 transfer arms 308 on the other side of the central axis 153). For example, using plane geometry of an X-Y plane, there may be two transfer arms 308 in a first quadrant, one transfer arm 308 in a second quadrant, one transfer arm 308 in a third quadrant, and two transfer arms in a fourth quadrant.

In both FIGS. 3A and 3B, the number of transfer arms 308 may be an even number or odd number. For example, the carousel 300 may have 5, 6, 7, 8, 9, 10, 11, 12, or any number of transfer arms that are higher or lower that those previously referenced. The number of transfer arms 308 may equal the number of process stations 160A-160F (shown in FIGS. 2A-2B).

FIG. 4 illustrates an example of a sweep of a carousel 400 and one transfer arm 408 through a metrology station 461 according to FIG. 1B. Here, the substrate is transferred along a path that extends along an imaginary circle in either direction. The transfer path is coincident with a metrology station, so that the substrate can pass under and/or above various metrology tools (i.e., double laser displacement tool(s), ellipsometry tool(s), UV/IR based spectrometer(s), FLIR camera(s), and/or CMOS camera(s)).

FIG. 5A is a side cross-sectional view of the multi-station processing chamber 150 viewed along the sectioning line 5A-5A illustrated in FIG. 2B, according to one or more embodiments. As shown in FIG. 5A, the multi-station processing chamber 150 includes a lower monolith 520 forming the lower portion or base of the multi-station processing chamber 150, and an upper monolith 522 that is sealed thereto and supported thereon. In some embodiments, the lower monolith 520 and the upper monolith 522 are welded, brazed or fused together by some desirable means to form a vacuum tight joint at the interface between the lower monolith 520 and the upper monolith 522. A plurality of pedestal assemblies 592, two of which are shown in FIGS. 5A, extend downwardly through the chamber base 518 of the lower monolith.

In some embodiments, the upper monolith 522 has a generally plate-like structure that has eight side facets that match those of the lower monolith 520. The upper monolith includes a chamber upper wall 516 that includes a central opening 513 disposed within a central region, and a plurality of upper process station openings 534, each corresponding to the location where a process kit assembly 580 and a source assembly 570 of the process stations 160A-160F are positioned. The multi-station processing chamber 150 includes a removable central cover 590 having a seal (not shown) that prevents the external environmental gases from leaking into a transfer region 501 when the transfer region 501 is maintained in a vacuum state by a vacuum pump (not shown). The upper monolith 522 includes a structural support assembly 510. The structural support assembly 510 is used to improve the parallelism of the source assembly 570 when the multi-station processing chamber 150 is under vacuum. The structural support assembly includes a plurality of mounting elements 502. The assembled upper monolith 522 typically has an average wall thickness (Z-direction) that is between 50 millimeters (mm) and 100 mm, and lower monolith 520 has an average wall thickness (Z-direction) that is between 75 mm and 150 mm. While not shown in FIGS. 5A-5B, in some embodiments, a second structural support assembly 510 is coupled to the chamber base 518 of the lower monolith 520.

In some embodiments, the combination of the second structural support assembly 510 and the structure of the chamber upper wall 516 is configured to minimize the angular deflection, or angular misalignment, of the processing surface 572A of a target 572, relative to a lateral plane that is parallel to the X-Y plane, to a tilt angle of between about 0.1 mm and about 0.25 mm measured edge-to-edge (e.g., rise) across a 300 mm diameter (e.g., run) that is centered about the center of the target 572. In some embodiments, the combination of the structural support assembly 510 and the structure of the chamber upper wall 516 is configured to minimize the angular misalignment of the processing surface 572A of the target 572 relative to the exposed surface of a substrate S, disposed on a substrate support 530 to a tilt angle of between about 0.1 mm and about 1 mm measured edge-to-edge (e.g., rise) across a 300 mm diameter (e.g., run) of the substrate S (e.g., between about 0.02 and 0.2 degree angle).

FIG. 5B is a side cross-sectional view of the multi-station processing chamber 150 viewed along the sectioning line 5B-5B illustrated in FIG. 2B, according to one or more embodiments. As shown in FIG. 5B, the multi-station processing chamber 150 includes a lower monolith 520 forming the lower portion or base of the multi-station processing chamber 150, and an upper monolith 522 that is sealed thereto and supported thereon. Here, a metrology station 161A-161F comprises an upper metrology module 162 disposed above a window 528 on the upper monolith 522, above the chamber lid 511. The window 528 may be fabricated from quartz, sapphire, or other material that is transparent. In this configuration, the upper metrology module 162 is positioned above the supporting portion 360 of the substrate handling system 145, such that a substrate positioned on the supporting portion 360 (e.g., blade) of the substrate handling system 145, will pass beneath the upper metrology module 162. Although not shown in FIG. 5B, the metrology station 161A-161 F can alternatively be configured to comprise both an upper metrology module 162 disposed above a window 528 on the upper monolith 522 and a lower metrology module 163 disposed beneath a window 528 on the lower monolith 520. In this configuration, the lower metrology module 163 is positioned such that a substrate in the transfer region 501 of the multi-station processing chamber 150 passes in-between the upper metrology module 162 and the lower metrology module 163.

As seen in FIG. 5B, in some configurations, a plurality of upper metrology station openings form the window 528 and are positioned in between the process stations 160A-160F and configured to view the surface of a substrate disposed on the supporting portion 360 of the carousel when it is positioned between process stations 160A-160F. Although only one window is shown in FIG. 5B, any number of windows can be used on any part of the upper monolith 522 and/or lower monolith 520. Alternatively, where no processing station or metrology stations are present, the transfer chamber includes a ceiling cover (not shown) to maintain the vacuum integrity of the multi-station processing chamber 150. Thus, the multi-station processing chamber 150 can be used with one or more of the metrology stations 161A-161F removed.

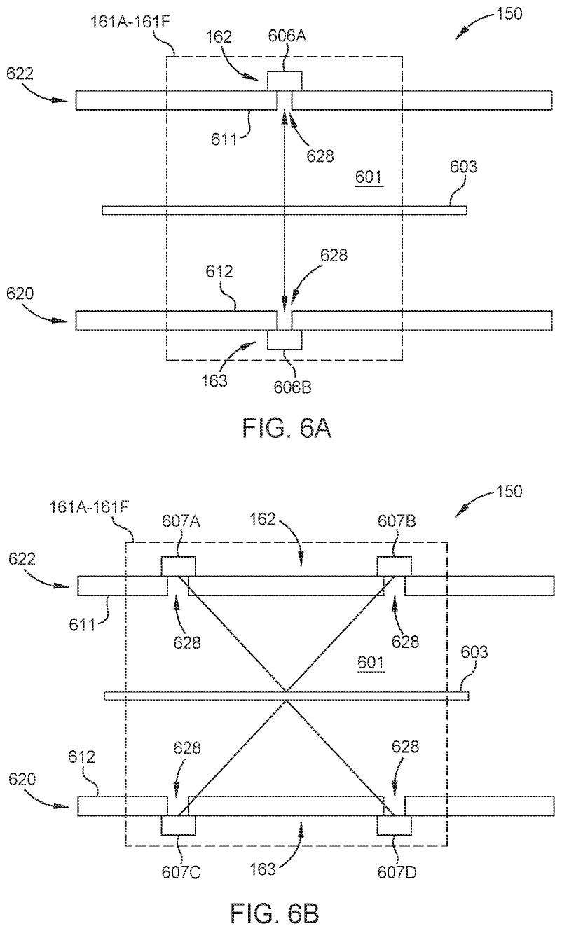

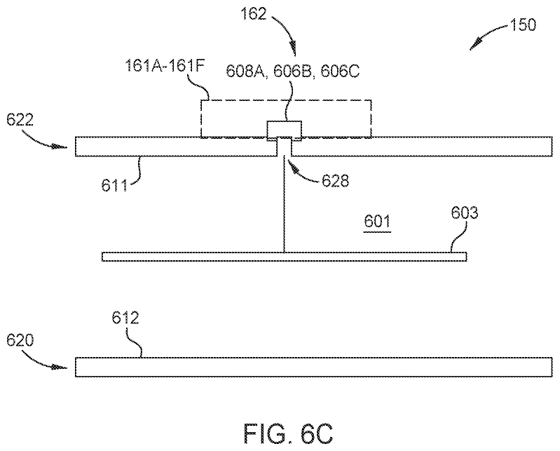

FIG. 6A is a side cross-sectional view of the multi-station processing chamber 150, with a metrology station 161A-161F. Here, the metrology station 161A-161F comprises a double laser displacement sensor system 606. The double laser displacement sensor system 606 includes an upper metrology module 162, and a lower metrology module 163. The upper metrology module 162 is disposed above a window 628 in an upper monolith 622, above a chamber lid 611. The lower metrology module 163 is disposed beneath a window 628 in a lower monolith 620, below a chamber base 612. The windows 628 may be fabricated from quartz, sapphire, or other material that is transparent. The upper metrology module 162, and the lower metrology module 163 are further positioned above and below an imaginary circle of the circular transfer path (now shown) of the substrate 603, so that a substrate 603 may be disposed therebetween in a transfer region 601 of the multi-station processing chamber 150. Typically, laser triangulation sensors contain a solid-state laser light source and a position sensitive detector (PSD), complementary metal-oxide semiconductor (CMOS) detector, or charge-coupled device (CCD). A laser beam is projected onto the substrate 603 and a portion of the beam is reflected back through focusing optics onto a detector. As the substrate 603 is moved, the laser beam proportionally moves on the detector. The signal from the detector is used to determine the relative distance to the substrate, and various measurements can be made. For example, in this configuration, the double laser displacement sensor system 605 may be used to determine the deformation of a substrate before and/or after processing in a process station 160A-160F. A deformation may comprise bow and/or warp of a substrate.

FIG. 6B is a side cross-sectional view of the multi-station processing chamber 150, with a metrology station 161A-161F. Here, the metrology station 161A-161F comprises an ellipsometry measurement tool 607. The ellipsometry measurement tool comprises an upper metrology module 162, and a lower metrology module 163. The upper metrology module 162 comprises a first emitter 607A and a first detector 607B. The lower metrology module 163 also comprises a second emitter 607C and a second detector 607D. The first emitter 607A and first detector 607B are both disposed above a window 628, in the upper monolith 622, above the chamber lid 611. The second emitter 607C, and second detector 607D, are both disposed beneath a window 628, in the lower monolith 620, below the chamber base 612. The windows 628 may be fabricated from quartz, sapphire, or other material that is transparent. The upper metrology module 162 and the lower metrology module 163 are further positioned above and below an imaginary circle of the circular transfer path (not shown) of the substrate 603, so that a substrate 603 may be disposed therebetween in the transfer region 601 of the multi-station processing chamber 150. Although in this configuration, the ellipsometry measurement tool 607 comprises an upper metrology module 162 having a first emitter 607A and first detector 607B and a lower metrology module 163 having a second emitter 607C and second detector 607D, the ellipsometry measurement tool 607 can comprise any number of emitters and detectors. Typically, in a reflection ellipsometer, a beam from a suitable light source (i.e., emitter) is passed through a variable polarizer to produce light of known polarization. The light interacts with the substrate and its polarization is modified. The modified polarization at the output of the system is measured by a polarization analyzer followed by a photodetector (i.e., detector). Because ellipsometry is a nondestructive measurement technique, and because it is extremely sensitive, and can measures small changes of film down to sub-monolayer of atoms or molecules, ellipsometry is particularly attractive for in-situ observation of substrates. Here, the ellipsometry measurement tool 607 may be used to monitor the growth and removal of thin films, and measure physical factors that affect the optical properties (such as electric and magnetic fields, and stress or temperature).

FIG. 6C is a side cross-sectional view of the multi-station processing chamber 150 with a metrology station 161A-161F. Here, the metrology station 161A-161F comprises an imaging device 608. Here, the imaging device 608 comprises an upper metrology module 162, and is disposed above the window 628 in the upper monolith 622, above the chamber lid 611. The window 628 may be fabricated from quartz, sapphire, or other material that is transparent. The imaging device 608 is further positioned above an imaginary circle of the circular transfer path (not shown) of the substrate 603, so that a substrate 603 may be disposed therebetween in the transfer region 601 of the multi-station processing chamber 150. The imaging device 608 may be used for a variety of purposes such as determining a deformation (e.g., bow or warp) of a substrate before and/or after processing in a process station 160A-160F.

In one configuration, the imaging device 608 may comprise an ultraviolet or infrared (UV/IR) based spectrometer 608A. Generally, a spectrometer 608A measures a spectral position of a minimum in the spectrum of the radiation that is reflected from the illuminated region of the substrate 603. The spectrometer 608A provides an electrical output signal related to a change in the spectral position of such a minimum with respect to a pre-selected (group or single) reference wavelength in the instrument range. The optical assembly, in the spectrometer 608A, may comprise passive optical components such as lens, mirrors, beam splitters, and the like.

In another configuration, the imaging device 608 may comprise a forward looking infrared (FLIR) camera 608B. Typically, an infrared camera 608B includes an optical system that focuses infrared energy onto a sensor array that contains thousands of detector pixels arranged in a grid. Each pixel in the sensor array reacts to the infrared energy focused on it and produces an electronic signal. The camera processor takes the sign from each pixel and applies a mathematical calculation to create a color map of the apparent temperature of the object. Each temperature value is assigned a different color. The resulting matrix of colors is sent to memory and to the camera's display as a temperature picture (thermal image) of that object.

In yet another configuration, the imaging device 608 may comprise a complementary metal oxide semiconductor (CMOS) camera 608C. Typically, in CMOS cameras 608C, the charge from the photosensitive pixel is converted to a voltage at a pixel site and the signal is multiplexed by row and column to multiple on chip digital-to-analog converters (DACs). Each site is essentially a photodiode and three transistors, performing the functions of resetting or activating the pixel, amplification and charge conversion, and selection or multiplexing. Unlike charge-coupled device (CCD) cameras, that have an array of capacitors each carrying an electric charge corresponding to the light intensity of a pixel, the CMOS camera 608C has a photodiode and a CMOS transistor at each pixel that allows the pixels to be amplified individually. By operating a matrix of switches, the pixel signals can be accessed directly and sequentially, and at a much higher speed than a CCD image sensor. In addition, having an amplifier for each pixel also reduces the noise that occurs when reading the electrical signals converted from captured light.

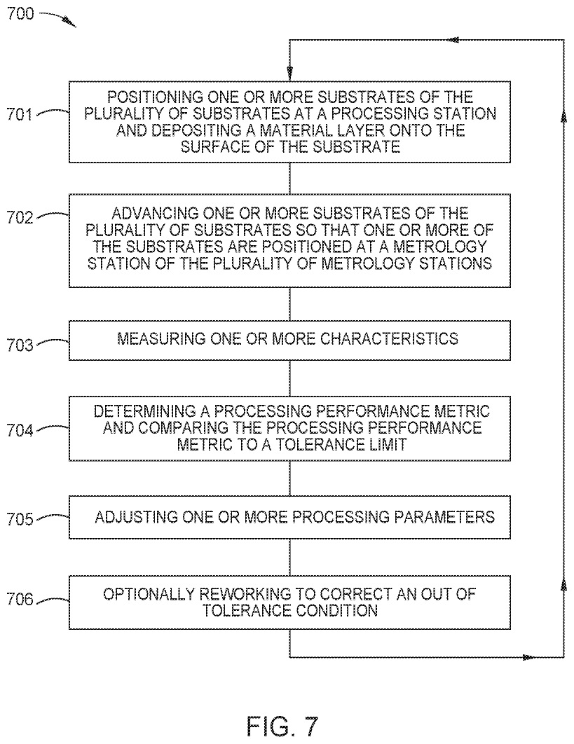

FIG. 7 is a diagram illustrating a method 700 of concurrently processing a plurality of substrates in a multi-station processing system, such as the substrate processing system 100 shown in FIG. 1. Generally, each of the plurality of substrates is moved through the substrate processing system 100 in a processing sequence that includes one or more material deposition processes, one or more material removal processes, or a combination thereof. The material deposition processes and/or material removal processes are collectively referred to herein as substrate processing operations. Before, after and/or between substrate processing operations, the method 700 generally includes determining one or more properties of the individual substrates, and optionally altering a processing parameter based on the determined one or more properties. Determining a property of the individual substrate includes measuring a property of the substrate (i.e., measuring one or more material layers on the substrate), using one of the plurality of metrology stations 161A-F, interposed between process stations 160A-160F.

At activity 701, the method 700 includes positioning a substrate at a processing station of the plurality of process stations 160A-160F and depositing a material layer onto the surface of the substrate using a material deposition process. Here, the material deposition process can include one, or a combination of, physical vapor deposition (PVD), atomic layer deposition (ALD), chemical vapor deposition (CVD). Typically, activity 701 is concurrently performed on a plurality of substrates each disposed at an individual station of the plurality of process stations 160A-160F. For example, one of the process stations 160A-160F, may be used to deposit a first material layer of a multi-layer film stack, while other process stations 160A-160F, may be used to deposit a different second material layer of the multilayer film stack. Thus, concurrent substrate processing operations are not limited to the same material and/or deposition processes and can include concurrent deposition of different layers of the multi-layer film stack so that one or more of the plurality of substrates is at a different stage of the multi-stage processing sequence. In some embodiments, one or more of the processing stations are configured to perform a material removal operation, such as a plasma-assisted etching operation.

At activity 702, the method 700 includes advancing the plurality of substrates so that one or more of the plurality of substrates are positioned at a metrology station of the plurality of metrology stations 161A-161F shown in FIG. 1. For example, in the embodiment shown in FIG. 1, each substrate of the plurality of substrates is simultaneously advanced from the process stations 160A-160F from which each substrate was just processed into the next corresponding metrology stations 161A-161F by the substrate handling system 145. The substrates may be advanced from the process stations 160A-160F in either a sequential or non-sequential manner. For example the central transfer robot may rotate in either a clockwise or counter-clockwise direction to move the plurality of substrates to the next metrology station 161A-161F in either transfer direction regardless of whether the next metrology station 161A-161F is adjacent to the previous process station 160A-160F.

At activity 703, the method 700 includes measuring one or more characteristics of the one or more substrates in the multi-station processing system by using a metrology system at a respective metrology station 161. The one or more characteristics can include characteristics such as material layer thickness, thickness uniformity across the surface of the substrate, and properties such as residual stress, composition, and/or other material or electrical properties, such as dielectric constant and/or sheet resistance. The one or more characteristics may be determined using any suitable metrology system and/or sensor that provides information, which can be used to determine a desired processing result related to the substrate and the material layers formed thereon. The metrology system, can include one or more double laser displacement tools, one or more ellipsometry measurement tools, one or more UV/IR based spectrometers, one or more forward looking infrared (FLIR) cameras, and/or one or more complementary oxide semiconductor (CMOS) cameras.

In some embodiments, measurements taken before and after processing of the substrate at a process station 160A-160F may be used to determine a characteristic of the deposited material layer. For example, substrate deflection measurements taken before and after a deposition operation may be used to determine a residual stress in the material layer based on the change in warp and/or bow in the substrate caused by depositing the material layer. In other embodiments, optical and electrical measurements of a material layer formed on the substrate can be used to determine the thickness alongside other optical, electrical and material properties. For example, pre-processing and post-processing measurements can be compared to determine processing uniformity of the material layer. Furthermore, measurements can be taken at a plurality of measurement sites, and can be taken across the entire surface (e.g., a scan or image). In some embodiments, the plurality of measurements taken from a plurality of measurement sites can be used to determine processing uniformity of the material layers of the substrate, such as material thickness uniformity.

A characteristic of a substrate need not be measured at each metrology station 161A-161F sequentially. For example, a first characteristic of a substrate can be measured at a first metrology station 161B, and a second characteristic of a substrate can be measured at a second metrology station 161A. In addition, a substrate can be selectively measured by any metrology station 161A-161F of the plurality of metrology stations 161A-161F in any order. For example, a first characteristic of a substrate can be measured at a first metrology station 161A, and second characteristic of a substrate can be measured at a second metrology station 161C.

At activity 704, the method 700 includes determining a processing performance metric, based on the one or more characteristics measured at activity 703, and comparing the processing performance metric to a tolerance limit to determine if an out of tolerance condition has occurred. The processing performance metric can be determined from a direct measurement taken at activity 703. For example, the performance metric can be determined by directly measuring material thickness, material layer uniformity, and material composition before or after processing the substrates. The performance metric can also be determined by comparing measurements taken before and after a substrate processing operation. For example, the performance metric can be determined by comparing pre-processing and post-processing characteristics of a film layer and/or film stack such as material thickness, material layer uniformity, and pre-material composition, and pre-processing and post-processing characteristics of a substrate such as wafer bow and/or warp. The tolerance limit may be determined by a desired set point, values above a desired lower threshold value, values below a desired upper threshold value, and all values between the desired lower threshold value and upper threshold value. Tolerance limits may include a combination of fixed values, e.g., pre-determined set points or thresholds, and values determined by one or more software algorithms, which are being executed on a controller of the multi-station system before, after, and/or concurrently with substrate processing and/or measurement operations.

At activity 705, the method 700 includes adjusting one or more processing parameters when the processing performance metric is outside of the tolerance limit. Typically, the adjustment is made to processing parameters that were used to deposit the material layer at activity 701. For example, if a material layer thickness on a substrate is determined to be outside of the tolerance limits at activity 704, one or more of the process parameters used to deposit the material layer, such as time, may be adjusted so that a material layer deposited on the next substrate processed at that station is within the tolerance limits.

At activity 706, the method 700 includes an optional process rework operation to correct an out of tolerance condition that was determined at activity 704. For example, if it is determined at activity 704 that an out of tolerance condition has occurred, the substrate having the out of tolerance condition may be processed a second time in the same or a different process chamber to deposit additional material or to remove portions of material when doing so would bring the material layer thickness into tolerance. Additionally, if it is determined that a performance metric is within a tolerance limit and no out of tolerance condition has occurred then, activity 705 can also include not adjusting a substrate processing parameter.

At activity 707, the method 700 includes advancing one or more substrates 603 of the plurality of substrates 603 into the next process stations 160A-160F and repeating activities 701-706.

What is claimed is:

1. A system for processing a plurality of substrates, comprising a multi-station processing system comprising:
a processing chamber comprising a chamber lid, one or more sidewalls, and a chamber base that collectively define a transfer volume;
a plurality of processing stations disposed in the transfer volume;
a substrate handling system;
a plurality of metrology stations, each respectively disposed between adjacent processing stations of the plurality of processing stations; and
a system controller, comprising a non-transitory computer readable medium configured to cause the multi-station processing system to perform a method, comprising:
processing a plurality of substrates at the plurality of processing stations;
advancing the plurality of substrates so that one or more of the plurality of substrates are positioned at a respective metrology station of the plurality of metrology stations;
measuring one or more characteristics of the one or more of the plurality of substrates in the multi-station processing system using a metrology system at the respective metrology station;
determining, a processing performance metric, based on the one or more characteristics, and comparing the processing performance metric to a tolerance limit to determine if an out of tolerance condition has occurred; and
adjusting one or more processing parameters when it is determined that an out of tolerance condition has occurred.

2. The system of claim 1, wherein the method further comprises reworking the one or more of the plurality of substrates to correct the out of tolerance condition when it is determined that an out of tolerance condition has occurred.

3. The system of claim 1, wherein an out of tolerance condition comprises one or more characteristics of a substrate, a film layer, or a film stack outside of the tolerance limit.

4. The system of claim 1, wherein the method further comprises advancing the plurality of substrates into a next process station of the plurality of process stations.

5. The system of claim 1, wherein the metrology system comprises a double laser displacement sensor system.

6. The system of claim 1, wherein the metrology system comprises an ellipsometry measurement tool.

7. The system of claim 1, wherein the metrology system comprises an ultraviolet or infrared based spectrometer.

8. The system of claim 1, wherein the metrology system comprises a forward looking infrared camera.

9. The system of claim 1, wherein the metrology system comprises a complementary metal oxide semiconductor tool.

10. A system for processing a plurality of substrates, comprising a multi-station processing system comprising:
a processing chamber comprising a chamber lid, one or more sidewalls, and a chamber base that collectively define a transfer volume;
a plurality of processing stations disposed in the transfer volume;
a substrate handling system;
a plurality of metrology stations, each respectively disposed between adjacent processing stations of the plurality of processing stations; and
a system controller, comprising a non-transitory computer readable medium configured to cause the multi-station processing system to perform a method comprising:
processing the plurality of substrates at the plurality of processing stations;
advancing the plurality of substrates so that one or more of the plurality of substrates are positioned at a respective metrology station of the plurality of metrology stations;
measuring one or more characteristics of the one or more of the plurality of substrates in the multi-station processing system using a metrology system at the respective metrology station;
determining a first processing performance metric based on the one or more characteristics, and comparing the first processing performance metric to a first tolerance limit to determine if an out of tolerance condition has occurred;
determining a second processing performance metric based on the one or more characteristics, and comparing the second processing performance metric to a second tolerance limit to determine if an out of tolerance condition has occurred;
adjusting one or more processing parameters when the first processing performance metric is outside of the first tolerance limit; and
adjusting one or more processing parameters when the second processing performance metric is outside of the second tolerance limit.

11. The system of claim 10, wherein the method further comprises reworking one or more of the plurality of substrates to correct an out of tolerance condition when it is determined that an out of tolerance condition has occurred.

12. The system of claim 11, wherein the out of tolerance condition comprises one or more of a film layer deposition, a film layer etch, a film stress, a wafer bow, or a wafer warp outside of the first tolerance limit or outside of the second tolerance limit.

13. The system of claim 11, wherein the method further comprises advancing one or more of the plurality of substrates into a next processing station of the plurality of processing stations.

14. The system of claim 10, wherein the metrology system comprises a double laser displacement sensor system.

15. The system of claim 10, wherein the metrology system comprises an ellipsometry measurement tool.

16. The system of claim 10, wherein the metrology system comprises an imaging device.

17. A system for processing a substrate, comprising:
a chamber comprising a chamber lid, one or more sidewalls, and a chamber base that collectively define a transfer volume;
a plurality of process stations disposed in the transfer volume, each of the plurality of process stations having a corresponding substrate processing position, wherein each substrate processing position collectively defines a circular transfer path, and wherein the process stations are fluidly isolated from the transfer volume;
a substrate handling system configured to move a plurality of substrates along the circular transfer path;
one or more metrology stations respectively disposed between adjacent processing stations of the plurality of processing stations; and
a system controller electronically coupled to the plurality of processing stations and the substrate handling system.

18. The system of claim 16, wherein one or more metrology stations comprise a laser bow measurement tool disposed on the chamber lid and chamber base.

19. The system of claim 16, wherein one or more metrology stations comprise an ellipsometry tool disposed on the chamber lid and chamber base.

20. The system of claim 16, wherein one or more metrology stations comprise an imaging tool disposed on the chamber lid.
